(19) United States
(12) Patent Application Publication
(10) Pub. No.: US 2008/0291635 A1
(43) Pub. Date: Nov. 27, 2008

(54) HEAT DISSIPATIVE STRUCTURE, OPTICAL PICKUP APPARATUS, AND OPTICAL RECORDING/REPRODUCING APPARATUS

(75) Inventor: Kenichi Tanaka, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/109,278

(22) Filed: Apr. 24, 2008

(30) Foreign Application Priority Data
May 25, 2007 (JP) 2007-139541

(51) Int. Cl. H05K 7/20

(52) U.S. Cl. 361/709

(57) ABSTRACT

A heat dissipative structure that offers high heat dissipation effect with a simple configuration, an optical pickup apparatus having the same, and an optical recording/reproducing apparatus are provided. A heat-dissipating component is provided for a heat-producing component. Heat generated in the heat-producing component can be transferred to the heat-dissipating component and released therefrom. The heat-dissipating component has a heat-dissipating plate, whereby a large surface area and high heat dissipation effect is obtained. The heat-dissipating portion having the heat-dissipating plate is disposed in a region including a side opposite from a heat-receiving portion which receives heat from the heat-producing component, whereby heat is released at a location as far away from the heat-receiving portion as possible. The heat dissipative structure which offers high heat dissipation effect can be implemented with a simple configuration, and the heat-producing component can be cooled effectively.

### CROSS-REFERENCE TO RELATED APPLICATION

This application claims priority to Japanese Patent Application No. 2007-139541, which was filed on May 25, 2007, the contents of which are incorporated herein by reference in its entirety.

### BACKGROUND OF THE INVENTION

1. Field of the Invention

The present invention relates to a heat dissipative structure that is provided in an optical pickup apparatus, as well as to an optical pickup apparatus having the heat dissipative structure and an optical recording/reproducing apparatus.

2. Description of the Related Art

There have been used optical pickup apparatuses for recording or reproducing digital data such as audio data, text data, and image data with respect to an optical information recording medium such as an optical disk. In such an optical pickup apparatus, recording of information is effected by allowing a light beam emitted from a semiconductor laser to be shone onto a recording surface of an optical information recording medium through an objective lens, and, on the other hand, reproduction of information is effected by allowing a reflected light beam resulting from reflection of the light beam shone onto the recording surface to be received by an optical detector.

In order to record or reproduce information at high speed by using the optical pickup apparatus, a semiconductor laser of high optical power will be required. Such a high-power semiconductor laser delivers an extremely large quantity of heat during oscillation. Furthermore, in keeping with the trend moving toward increasingly greater information recording densities, higher and higher optical power has come to be demanded of the semiconductor laser. As a result, it has already been usual for the surface temperature of a laser to reach 100° C. during oscillation. In addition, since a great driving current arises at this time, it follows that the surface temperature of a laser driving IC often exceeds 100° C.

Because of its highly temperature-sensitive nature, it is said that the semiconductor laser may serve also as a thermometer. Therefore, under high temperature conditions, the semiconductor laser suffers from worsening characteristics deterioration, such as a decrease in power output, an ensuing increase in driving current, and a shortening of the service lifespan of the element. Furthermore, in a case where the semiconductor laser is bonded to a casing such as a housing with use of an adhesive, the adhesive could be softened at high temperature, which results in a change in the fixed position of the semiconductor laser. This gives rise to a possibility of a degradation in the performance capabilities of the optical pickup apparatus. In addition, the laser driving IC cannot be operated properly when the temperature exceeds a predetermined level.

Thus, the optical pickup apparatus is provided with a heat-producing component, and the heat generated in the heat-producing component could cause adverse effects. Therefore, how the heat generated in the heat-producing component is to be dissipated is of a significant challenge to be addressed, and various proposals have been made to date in connection therewith. Structures for heat dissipation fall into two broad categories: a structure that exploits thermal conduction and an air-cooled structure (a structure that exploits radiation and convection phenomena).

The former, namely the structure exploiting thermal conduction is a structure in which the heat generated in the heat-producing component is thermally transferred to a housing which is large in thermal capacity and in surface area to be exposed to air. In this structure, as is shown in Japanese Unexamined Patent Publication JP-A 10-233024 (1998) for example, its advantageous effect can be enhanced by increasing the area of contact between the heat-producing component and the housing. However, the enhanced effect provided by the structure can be obtained in so far as the housing offers large thermal capacity, and the degrees of heat emission into the air and air convection are great. There are cases where, in the optical pickup apparatus, the wall thickness of the housing is reduced to a minimum for the purpose of weight reduction and cost reduction, or some optical pickup apparatuses employ a housing made of resin. Inconveniently, in such cases, the effect of lowering the temperature of the heat-producing component obtained through the transfer of heat to the housing will be impaired.

The latter, namely the air-cooled structure is a structure that exploits a current of air generated at the time of rotation of an optical disk or a current of air generated by a fan for air-cooling, or a structure that exploits radial displacement of the optical pickup apparatus relative to an optical disk. The air-cooled structure is shown in Japanese Unexamined Patent Publications JP-A 2002-25243, JP-A 2005-339737, and JP-A 2004-273043, for example. In the structure according to JP-A 2002-25243, a propeller or a fin is rotated by a spindle motor, and a resultant current of air is utilized. In this structure, however, the number of constituent components is increased, which leads to a cost increase and upsizing. Furthermore, due to the application of an additional load to the motor, the heat generated by the motor cancels out the air-cooling effect. In the structure according to JP-A 2005-339737, as is the case with JP-A 2002-25243, an airflow is generated by driving an airflow generating section by means of a spindle motor, and the airflow is directed to a laser light emitting section. Also in the structure according to JP-A 2005-339737, as is the case with JP-A 2002-25243, the number of constituent components is increased, which leads to a cost increase and upsizing. Furthermore, due to the application of an additional load to the motor, the heat generated by the motor cancels out the air-cooling effect. In the structure according to JP-A 2004-273043, a housing includes a diagonal plate which protrudes in a slanting downward direction from a location at which a laser driving circuit is mounted. In accompaniment with the horizontal movement of the housing, a current of air is generated by the diagonal plate. By exploiting the flow of the air current, the laser driving circuit is cooled down. In this structure, however, a sufficient heat dissipation effect cannot be attained. In particular, it is impossible to provide an air-cooling effect during long-time writing of information that is of primary importance.

### SUMMARY OF THE INVENTION

An object of the invention is to provide a heat dissipative structure that offers a high heat dissipation effect with a simple configuration, an optical pickup apparatus having the heat dissipative structure, and an optical recording/reproducing apparatus.

The invention provides a heat dissipative structure that is to be provided in an optical pickup apparatus in which a heat-producing component is mounted, comprising:

a heat-dissipating component to be thermally connected to the heat-producing component, the heat dissipating component having a heat-receiving portion which receives heat from the heat-producing component, and a heat-dissipating portion disposed in a region including a side opposite from the heat-receiving portion,

wherein the heat-dissipating portion includes a heat-dissipating plate for releasing heat.

According to the invention, the heat-dissipating component is provided for the heat-producing component. In this case, the heat generated in the heat-producing component can be transferred to the heat-dissipating component and thus released therefrom. Being provided with the heat-dissipating plate, the heat-dissipating component is large in surface area and is thus capable of providing a high heat dissipation effect. Moreover, since the heat-dissipating portion in which is provided the heat-dissipating plate is disposed in the region including the side opposite from the heat-receiving portion which receives heat from the heat-producing component, it follows that the heat can be released at a location as far away from the heat-producing component as possible. With this ideal construction, it is possible to implement a heat dissipative structure which offers a high heat dissipation effect with a simple configuration. Accordingly, the heat-producing component can be cooled down effectively.

In the invention, it is preferable that the heat-producing component is a semiconductor laser element or a laser driving IC.

According to the invention, the heat generated in the semiconductor laser element or the laser driving IC can be dissipated properly, and thereby the semiconductor laser element or the laser driving IC can be cooled down effectively. Accordingly, the semiconductor laser element or the laser driving IC is allowed to keep up good operating conditions with stability.

Further, in the invention, it is preferable that the heat-dissipating plate is formed of a planar-shaped platy member.

According to the invention, being formed of a planar-shaped platy member, the heat-dissipating plate can be implemented with a simple configuration. Accordingly, the heat dissipative structure can be produced with ease.

Further, in the invention, it is preferable that, in the heat-dissipating component, at least part of the heat-dissipating portion is applied with a surface treatment to obtain higher thermal emissivity.

According to the invention, at least part of the heat-dissipating portion is applied with a surface treatment to obtain higher thermal emissivity. This makes it possible to increase the thermal emissivity of the heat-dissipating component and thereby enhance the heat dissipation effect.

Further, in the invention, it is preferable that, in the heat-dissipating component, at least part of the heat-dissipating portion is applied with a matte black coating to obtain higher thermal emissivity.

According to the invention, at least part of the heat-dissipating portion is applied with a matte black coating to obtain higher thermal emissivity. This makes it possible to increase the thermal emissivity of the heat-dissipating component and thereby enhance the heat dissipation effect.

Further, in the invention, it is preferable that, in the heat-dissipating component, at least part of the heat-dissipating portion is made to have a rough face.

According to the invention, at least part of the heat-dissipating portion is made to have a rough face. This makes it possible to increase the surface area of the heat-dissipating component without the necessity of increasing the outer dimension of the heat-dissipating component, and thereby enhance the heat dissipation effect.

Further, in the invention, it is preferable that the heat-dissipating portion is made larger in surface area than the heat-receiving portion.

According to the invention, the heat-dissipating portion is made larger in surface area than the heat-receiving portion. This makes it possible to facilitate the release of heat received by the heat-receiving portion from the heat-dissipating portion, and thereby prevent the heat-dissipating component itself from acquiring a high temperature that will eventually impair the heat dissipation effect. Accordingly, the high heat dissipation effect can be maintained for a longer period of time. That is, even if a reproduction operation or a recording operation is carried out for a long time, the heat-producing component can be kept in a low-temperature state.

Further, in the invention, it is preferable that the heat-dissipating component and the heat-producing component are indirectly connected to each other via a connection layer having thermal conductivity.

According to the invention, the heat-dissipating component and the heat-producing component are indirectly connected to each other via the connection layer. By using the connection layer in this way, it is possible to establish connection between the heat-producing component and the heat-dissipating component with ease.

Further, in the invention, it is preferable that the connection layer is formed by injection of a material having fluidity.

According to the invention, the connection layer is formed by a material having fluidity. This makes it possible to prevent a layer of air from lying between the heat-producing component and the heat-dissipating component, and thereby establish thermal connection between the heat-producing component and the heat-dissipating component without fail.

Further, in the invention, it is preferable that in the heat-dissipating component is formed at least one opening for injecting the material having fluidity in between the heat-dissipating component and the heat-producing component.

According to the invention, in the heat-dissipating component is formed an opening for injecting the material having fluidity. This makes it possible to facilitate the injection of the liquid-state material and thereby allow easy formation of the connection layer.

Further, in the invention, it is preferable that the heat-dissipating component has a plurality of heat-dissipating plates that are spacedly arranged side by side.

According to the invention, with the arrangement of a plurality of heat-dissipating plates in the heat-dissipating component, it is possible to increase the surface area of the heat-dissipating component and thereby enhance the heat dissipation effect.

Further, in the invention, it is preferable that the heat-dissipating plates have different dimensions.

According to the invention, a plurality of heat-dissipating plates to be provided have different dimensions. In this case, all of the heat-dissipating plates are allowed to make contact with an air current with ease, wherefore the heat dissipation effect can be enhanced.

Further, in the invention, it is preferable that the heat-dissipating component is thermally connected to a housing of the optical pickup apparatus.

According to the invention, the heat-dissipating component is connected to the housing. This allows the heat that the heat-dissipating component receives from the heat-producing component to travel to the housing. In this way, by transferring heat to the housing which is large in thermal capacity and in surface area, it is possible to enhance the heat dissipation effect even further.

The invention provides an optical pickup apparatus comprising:

a heat-producing component; and

the heat dissipative structure described hereinabove.

According to the invention, it is possible to implement an optical pickup apparatus that has the heat dissipative structure by which the heat liberated from the heat-producing component can be released with a high heat dissipation effect. Accordingly, it is possible to implement an optical pickup apparatus that is operated with stability without causing heat-induced malfunction.

Further, in the invention, it is preferable that the optical pickup apparatus is slidably disposed on a plurality of shafts arranged substantially in parallel with each other and is thus movable reciprocally along each of the shafts, that the optical pickup apparatus is designed to perform at least one of information reproduction and information recording with respect to an optical disk which is arranged substantially in parallel with the axis of each of the shafts, and that the heat-dissipating plate is formed as a planar-shaped plate extending circumferentially about the axis of rotation of the optical disk, with a normal to its planar-shaped portion extending in a direction intersected by a recording surface of the optical disk.

According to the invention, the heat-dissipating plate is formed as a planar-shaped plate extending circumferentially about the axis of rotation of the optical disk. In this construction, an air current generated in accompaniment with the rotation of the optical disk flows along the heat-dissipating plate. This helps facilitate heat exchange between the heat-dissipating plate and the air current, wherefore heat can readily be released through the heat-dissipating plate. Accordingly, a high heat dissipation effect can be attained. Moreover, the heat-dissipating plate is disposed inclined so as for the normal to the planar-shaped portion to extend in a direction intersected by the recording surface of the optical disk. This makes it possible to increase the surface area of the heat-dissipating plate while minimizing the dimension of the heat-dissipating plate in a direction substantially parallel to the axis of rotation of the optical disk. In this way, it is possible to implement a compact optical pickup apparatus which offers a high heat dissipation effect.

Further, in the invention, it is preferable that the optical pickup apparatus is slidably disposed on a plurality of shafts arranged substantially in parallel with each other and is thus movable reciprocally along each of the shafts, that the optical pickup apparatus is designed to perform at least one of information reproduction and information recording with respect to an optical disk which is arranged substantially in parallel with the axis of each of the shafts, and that the heat-dissipating plate is formed as a planar-shaped plate extending in a direction substantially radial to the optical disk, with a normal to its planar-shaped portion extending in a direction intersected by the recording surface of the optical disk.

According to the invention, the heat-dissipating plate is formed as a planar-shaped plate extending in a direction substantially radial to the optical disk. In this construction, a collision of air currents generated in accompaniment with the rotation of the optical disk takes place, thus enabling agitation of air around the heat-dissipating component. This helps facilitate heat exchange between the heat-dissipating component and the air therearound, wherefore heat can readily be released through the heat-dissipating plate. Accordingly, a high heat dissipation effect can be attained. Moreover, the heat-dissipating plate is disposed inclined so as for the normal to the planar-shaped portion to extend in a direction intersected by the recording surface of the optical disk. This makes it possible to increase the surface area of the heat-dissipating plate while minimizing the dimension of the heat-dissipating plate in a direction substantially parallel to the axis of rotation of the optical disk. In this way, it is possible to implement a compact optical pickup apparatus which offers a high heat dissipation effect.

The invention provides an optical recording/reproducing apparatus in which is mounted the optical pickup apparatus described hereinabove.

According to the invention, there is implemented an optical recording/reproducing apparatus which incorporates the optical pickup apparatus having the heat dissipative structure. Accordingly, it is possible to implement an ideal optical recording/reproducing apparatus incorporating the optical pickup apparatus that is operated with stability without causing heat-induced malfunction.

### BRIEF DESCRIPTION OF THE DRAWINGS

Other and further objects, features, and advantages of the invention will be more explicit from the following detailed description taken with reference to the drawings wherein:

FIG. 1 is a sectional view showing an optical pickup apparatus having a heat dissipative structure in accordance with one embodiment of the invention;

FIG. 2 is a front view showing the optical pickup apparatus;

FIG. 3 is a sectional view of the optical pickup apparatus taken along the section line S3-S3 of FIG. 2;

FIG. 4 is a front view showing part of an optical recording/reproducing apparatus in which is mounted the optical pickup apparatus;

FIG. 5 is a front view showing an optical system mounted in the optical pickup apparatus in simplified form;

FIG. 6 is a side view showing the vicinities of an objective lens of the optical system in simplified form;

FIG. 7 is a front view showing the laser element;

FIG. 8 is a plan view showing the laser element

FIG. 9 is a bottom view showing the laser element;

FIG. 10 is a sectional view showing the laser element in a state of being mounted in a housing;

FIG. 11 is a plan view showing the laser element mounted in the housing;

FIG. 12 is a bottom view showing the laser element mounted in the housing;

FIG. 13 is a front view showing the heat dissipative structure;

FIG. 14 is a sectional view of the heat dissipative structure taken along the section line S14-S14 of FIG. 13;

FIG. 15 is a side view showing the heat dissipative structure;

FIG. 16 is a front view showing the heat dissipative structure attached to the laser element;

FIG. 17 is a sectional view of the heat dissipative structure taken along the section line S17-S17 of FIG. 16;

FIG. 18 is a side view showing the heat dissipative structure attached to the laser element;

FIG. 19 is a front view showing a heat dissipative structure in accordance with another embodiment of the invention;

FIG. 20 is a sectional view of the heat dissipative structure taken along the section line S20-S20 of FIG. 19;

FIG. 21 is a sectional view of the heat dissipative structure taken along the section line S21-S21 of FIG. 19;

FIG. 22 is a front view showing a heat dissipative structure in accordance with still another embodiment of the invention;

FIG. 23 is a sectional view of the heat dissipative structure taken along the section line S23-S23 of FIG. 22; and

FIG. 24 is a sectional view of the heat dissipative structure taken along the section line S24-S24 of FIG. 22.

### DETAILED DESCRIPTION

Now referring to the drawings, preferred embodiments of the invention are described below.

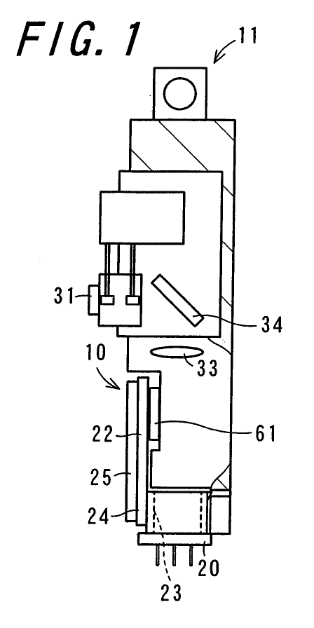

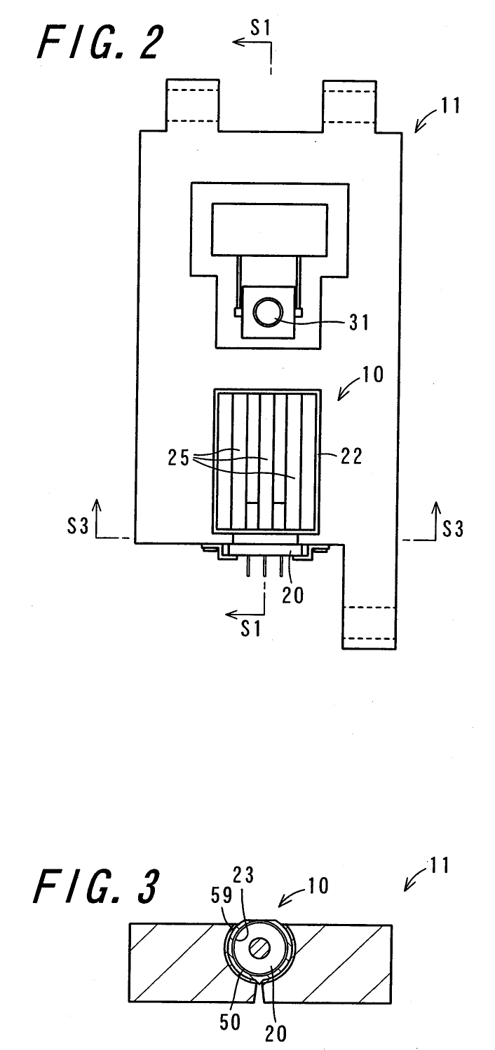

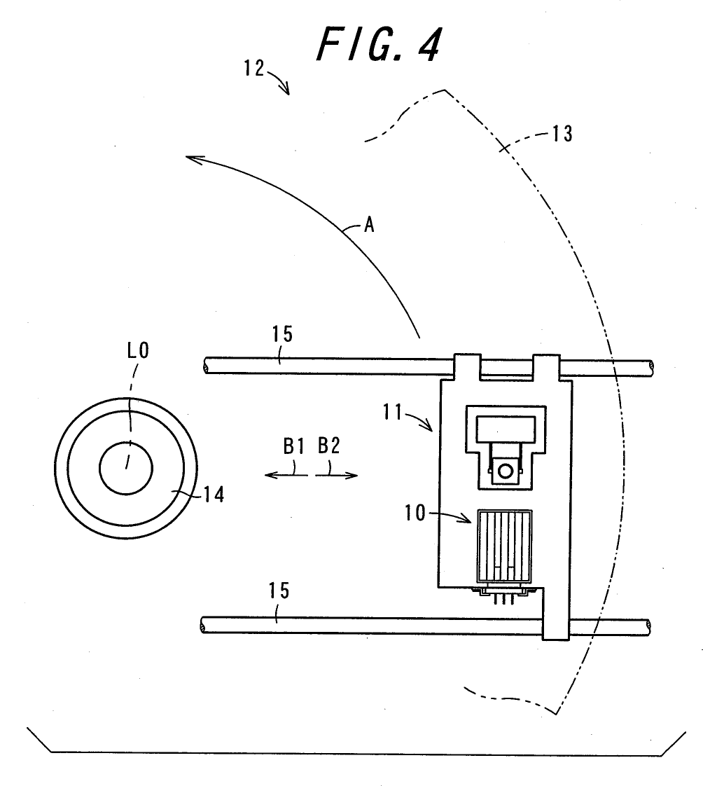

FIG. 1 is a sectional view showing an optical pickup apparatus 11 having a heat dissipative structure 10 in accordance with one embodiment of the invention. FIG. 2 is a front view showing the optical pickup apparatus 11. FIG. 3 is a sectional view of the optical pickup apparatus 11 taken along the section line S3-S3 of FIG. 2. FIG. 4 is a front view showing part of an optical recording/reproducing apparatus 12 in which is mounted the optical pickup apparatus 11. In FIG. 1, there is shown the cross section of the optical pickup apparatus 11 taken along the section line S1-S1 of FIG. 2. The optical recording/reproducing apparatus 12 is designed to perform at least one of information recording and information reproduction with respect to an optical disk 13 which is an optical information recording medium. In the following description, where mention is made of any of recording and reproduction unspecifically, the term “recording/reproduction” is used. The optical disk 13 is, for example, a DVD or a CD-ROM, although other media can also be used. Moreover, target information of recording/reproduction is, for example, digital data representing audio, text, image, etc, although other types of information can also be a target.

The optical recording/reproducing apparatus 12 is designed to perform recording/reproduction of information by applying light onto the recording surface of the optical disk 13 by means of the optical pickup apparatus 11 while rotating the optical disk 13 attached to a turn table 14 about an axis of rotation L0 in a rotational direction A. The optical recording/reproducing apparatus 12 includes a plurality of shafts 15 according to the present embodiment that are arranged substantially in parallel with the optical disk 13 attached to the turn table 14. The shafts 15 are arranged substantially in parallel with each other. The optical pickup apparatus 11 is disposed slidably on each of the shafts 15 so that it can be moved reciprocally along each of the shafts 15. Accordingly, the optical pickup apparatus 11 can be displaced radially inwardly (B1), as well as displaced radially outwardly (B2), relative to the optical disk 13.

The optical pickup apparatus 11 includes a semiconductor laser element acting as a light-emitting element (hereinafter referred to simply as “laser element”) 20. The semiconductor laser element 20 is used as a source of light which is utilized for recording/reproduction of information. The laser element 20 liberates heat during oscillation, and consequently its temperature could be raised to, for example, 100° C. Thus, the laser element 20 is a heat-producing component; that is, heat is evolved on the operation of the laser element 20. Furthermore, liberation of heat leads to deterioration in performance capabilities. Under the circumstances, in order to release the heat generated in the laser element 20 to another area, to cool the laser element 20 down, and to prevent a temperature rise in the laser element 20, the heat dissipative structure 10 embodying the invention is provided.

The heat dissipative structure 10 includes a heat-dissipating component 22 which is thermally connected to the laser element 20. The heat-dissipating component 22 is composed of a heat-receiving portion 23 and a heat-dissipating portion 24 which is disposed in a region including the side opposite from the heat-receiving portion 23. The heat-dissipating portion 24 includes a heat-dissipating plate 25 for releasing heat.

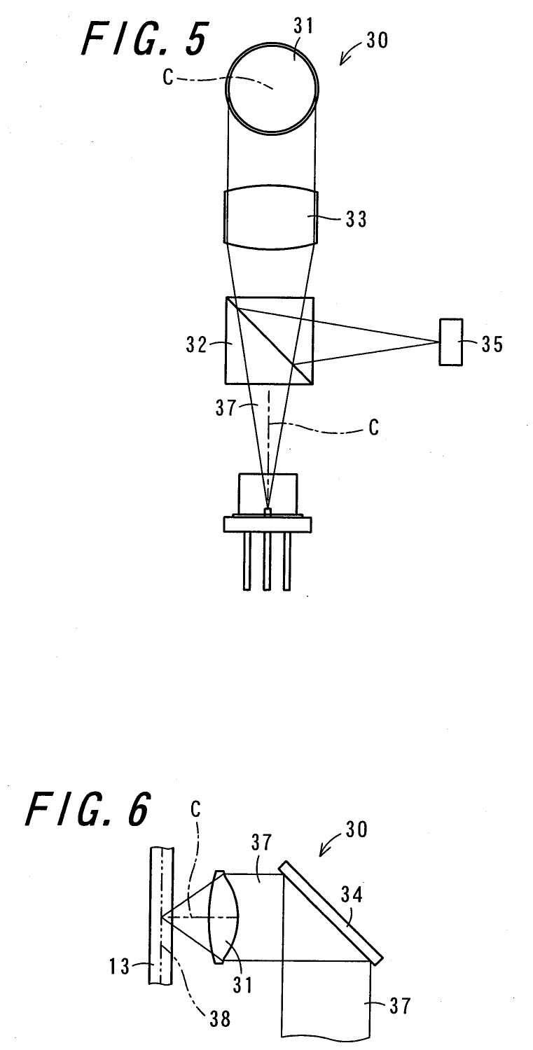

FIG. 5 is a front view showing an optical system 30 in simplified form. The optical system 30 is mounted in the optical pickup apparatus 11. FIG. 6 is a side view showing the vicinities of an objective lens 31 of the optical system 30 in simplified form. The optical pickup apparatus 11 includes the optical system 30, and the laser element 20 is incorporated in this optical system 30. The optical system 30 is composed of the laser element 20, a beam splitter 32, a collimator lens 33, a raising mirror 34, the objective lens 31, and a light detector 35.

The laser element 20 is so disposed that an optical axis C of an outgoing light beam 37 is parallel to the optical disk 13. The light beam 37 emitted from the laser element 20 is converted into parallel light by the collimator lens 33 and is reflected from the raising mirror 34, whereupon the optical axis C undergoes a ninety degree turn. Then, the parallel light beam is condensed and shone onto a recording surface 38 of the optical disk 13 by the objective lens 31. The optical axis C of the light beam 37 shone on the optical disk 13 is perpendicular to the optical disk 13.

Between the laser element 20 and the collimator lens 33 is disposed the beam splitter 32. The light beam 37 shone on the optical disk 13 is reflected from the recording surface 38 and is directed, through the objective lens 31, the raising mirror 34, and the collimator lens 33, to the beam splitter 32. The light beam 37 is caused to change its direction at 90 degrees in the beam splitter 32, and is then received by the light detector 35. By virtue of the optical system 30 thus constructed, the light emitted from the laser element 20 can be shone onto the optical disk 13, and reflected light resulting from reflection of the light can be received by the light detector.

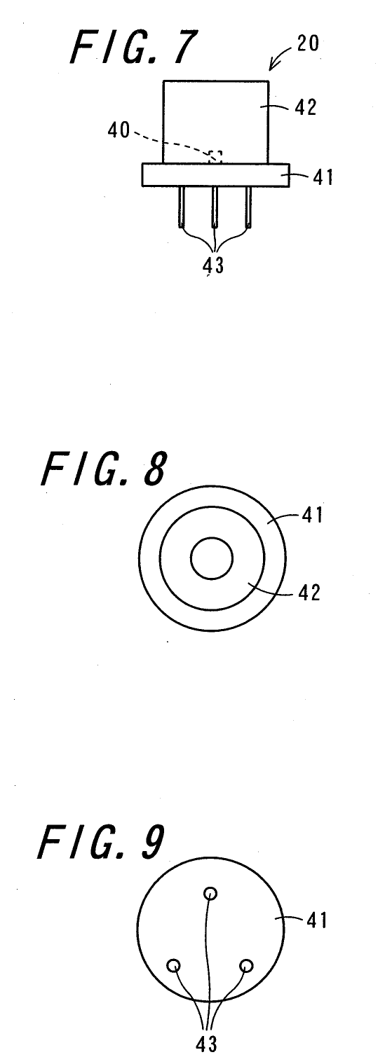

FIG. 7 is a front view showing the laser element 20. FIG. 8 is a plan view showing the laser element 20. FIG. 9 is a bottom view showing the laser element 20. The laser element 20 is constructed by mounting a semiconductor laser chip 40 on a stem 41 and sealing them with a cap 42. The laser element 20 is oscillated by the passage of electric current through the semiconductor laser chip 40 via a lead 43 disposed on the stem 41, whereby laser light is emitted therefrom. In the semiconductor laser chip 40, heat is generated in accompaniment with the oscillation. The semiconductor laser chip 40 and a combination of the stem 41 and the cap 42 make contact with each other at a very low thermal resistance. The heat generated in the semiconductor laser chip 40 is transmitted to the stem 41 and the cap 42. The semiconductor laser chip 40 has been confirmed to be raised in temperature in proportion to a rise in temperature in the stem 41 and the cap 42.

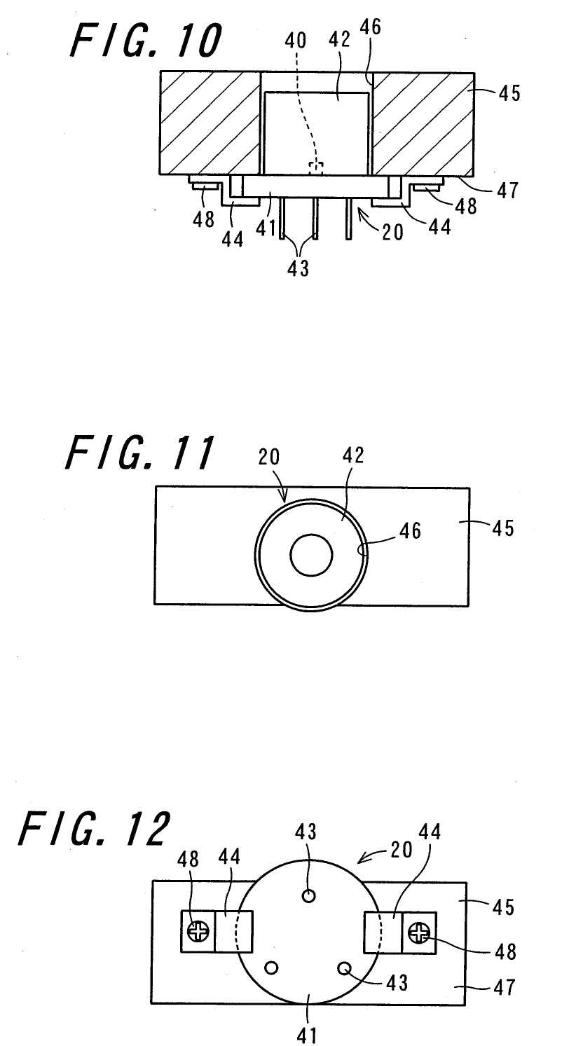

FIG. 10 is a sectional view showing the laser element 20 in a state of being mounted in a housing 45. FIG. 11 is a plan view showing the laser element 20 mounted in the housing 45. FIG. 12 is a bottom view showing the laser element 20 mounted in the housing 45. The housing 45 has formed in its region in which is disposed the laser element 20 a hole 46 extending perpendicularly with respect to a predetermined mounting surface 47, and a mounting spring 44 is disposed on the mounting surface 47 with a screw 48. In mounting the laser element 20 in the housing 45, the cap 42 is inserted into the hole 46 with a fit therewith and the stem 41 is brought into abutment with the mounting surface 47 of the housing 45. In this state, the laser element 20 is secured in place by the mounting spring 44. The cap 42 and the housing 45 are spaced apart entirely circumferentially.

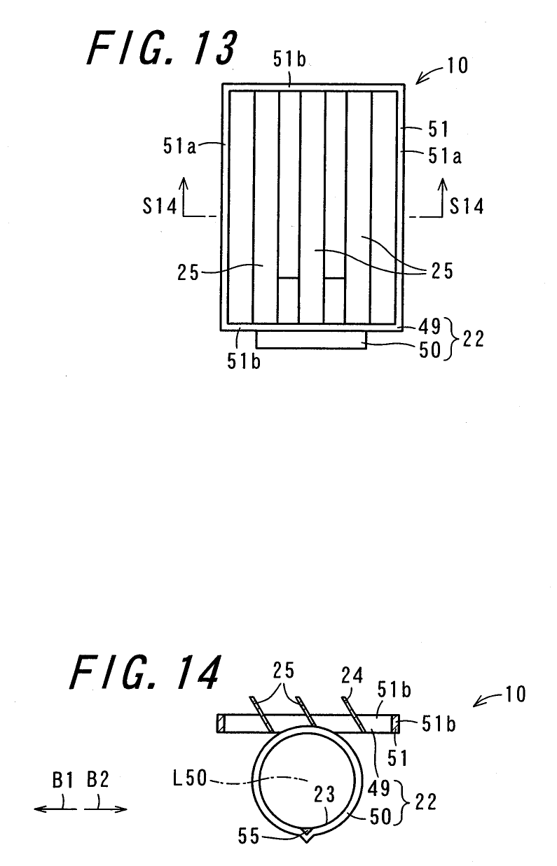

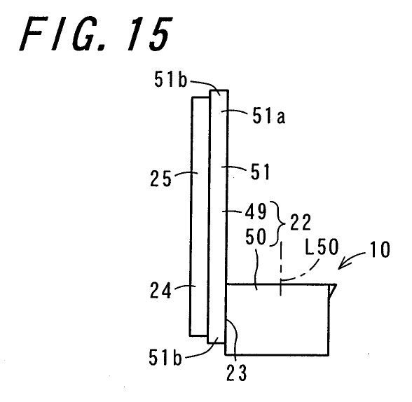

FIG. 13 is a front view showing the heat dissipative structure 10. FIG. 14 is a sectional view of the heat dissipative structure 10 taken along the section line S14-S14 of FIG. 13. FIG. 15 is a side view showing the heat dissipative structure 10. The heat dissipative structure 10 includes at least the heat-dissipating component 22. This heat-dissipating component 22 is, at its heat-receiving portion 23, thermally connected to at least one of the stem 41 and the cap 42 of the laser element 20. The heat-receiving portion 23 is preferably kept in direct contact with the laser element 20, although the contact between them may be made in an indirect manner. In this embodiment, the heat-dissipating component 22 is connected indirectly to the laser element 20.

The heat-dissipating component 22 is composed of a heat-dissipating component main body 49 shaped like a drainboard and a mounting tubular body 50 formed in the shape of a cylinder. The heat-dissipating component main body 49 includes a rectangular framework 51 and a plurality of heat-dissipating plates 25 which are supported by and are disposed inside the framework 51. The heat-dissipating component main body 49 is provided with a plurality of, for example, three pieces of the heat-dissipating plates 25. The heat-dissipating plates 25 are similarly configured, are each formed as a strip-like rectangular plate, and are arranged in parallel with one another. Moreover, the heat-dissipating plates 25 are arranged in parallel with one pair of parallely arranged edge portions 51a of the framework 51, and are so disposed as to extend between the other pair of edge portions 51b that is perpendicular to one pair of edge portions 51a. Further, each of the heat-dissipating plates 25 is disposed in such a manner that a normal thereto, which is a straight line extending in the direction of thickness of the heat-dissipating plate 25, is inclined relative to a virtual plane along the edge portions 51a and 51b of the framework 51 and is also inclined relative to a direction perpendicular to the virtual plane (hereinafter referred to as “the thicknesswise direction of the framework 51”). In addition, the heat-dissipating plates 25 are each so disposed as to protrude not on one thicknesswise side but on the other thicknesswise side with respect to the framework 51. The heat-dissipating component main body 49 is so configured as to provide air permeability in the thicknesswise direction.

The mounting tubular body 50 is formed in the shape of a cylinder. The mounting tubular body 50 is placed on one thicknesswise side of the heat-dissipating component main body 49 and is, at its outer periphery, coupled to the heat-dissipating component main body 49. The heat-dissipating component main body 49 and the mounting tubular body 50 are arranged in such a manner that an axis L50 of the mounting tubular body 50 is parallel to one pair of edge portions 51a of the framework 51. The mounting tubular body 50 is coupled to one of the other pair of edge portions 51b of the framework 51. In this way, the heat-dissipating component 22 comprises a combination of the heat-dissipating component main body 49 and the mounting tubular body 50 in a single-piece construction.

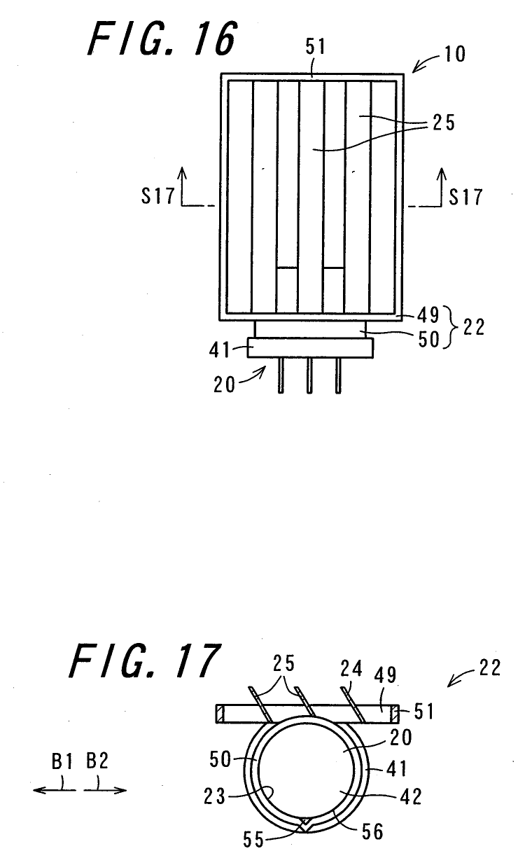

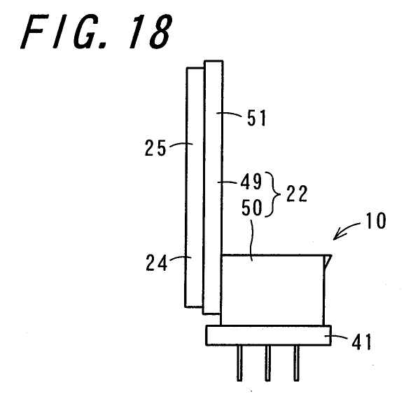

FIG. 16 is a front view showing the heat dissipative structure 10 attached to the laser element 20. FIG. 17 is a sectional view of the heat dissipative structure 10 taken along the section line S17-S17 of FIG. 16. FIG. 18 is a side view showing the heat dissipative structure 10 attached to the laser element 20. The heat-dissipating component 22 is disposed in such a manner that the cap 42 of the laser element 20 is inserted into the mounting tubular body 50 with a fit therewith, the outer peripheral surface of the cap 42 and the inner peripheral surface of the mounting tubular body 50 confront each other, and one end face of the mounting tubular body 50 in an axial direction faces the stem 41. The heat-dissipating component main body 49 is so disposed as to protrude beyond the other axial end face of the mounting tubular body 50 in the opposite direction to the stem 41 and extend in a direction axially of the mounting tubular body 50.

The heat-dissipating component 22 is so designed that the heat generated in the semiconductor laser chip 40 of the laser element 20 is received by the mounting tubular body 50, is then transmitted from the mounting tubular body 50 to the heat-dissipating component main body 49, and is eventually released from the heat-dissipating component main body 49. The heat-dissipating component 22 receives, at the inner peripheral surface portion and one axial end face of the mounting tubular body 50, the heat liberated from the laser element 20. That is, in the heat-dissipating component 22, the inner peripheral surface portion and one axial end face of the mounting tubular body 50 serve as the heat-receiving portion 23 on one hand, and the region which includes the other thicknesswise side of the heat-dissipating component main body 49 and is thus different from the heat-receiving portion 23 serves as the heat-dissipating portion 24 on the other hand. At least the heat-dissipating component main body 49 serves as the heat-dissipating portion 24.

The area of the heat-receiving portion 23, namely the cross-sectional area of the junction between the heat-dissipating component 22 and the mounting tubular body 50, is preferably set at 1 mm². By setting the cross-sectional area at least at 1 mm² or above, it is possible to ensure that, as compared with the quantity of heat liberated from the laser element 20 in a unit of time, the quantity of heat transmitted from the laser element 20 to the heat-dissipating component 22 in a unit of time is made larger. For example, the heat-dissipating component 22 is made from metal and is designed to have a thermal conductivity as high as, for example, 10 W/m·K or above. This makes it possible to transfer the heat received from the laser element 20 to the heat-dissipating portion 24 thereby to achieve heat dissipation in an ideal manner.

As a material for forming at least each of the heat-dissipating plates 25 or, in this embodiment, the heat-dissipating component 22, for example, readily-workable phosphor bronze adaptable for spring formation is used. In the case of using this spring-adaptable phosphor bronze, the heat-dissipating component 22 will have a thermal conductivity of 67 W/m·K. Moreover, the stem 41 and the cap 42 of the laser element 20 are each made of iron, for example, and have a thermal conductivity of 84 W/m·K.

The admission of heat can also be effected by a construction in which the cap 42 and the stem 41 of the laser element 20 and the mounting tubular body 50 are kept in direct contact with each other. In this construction, however, since contact is provided between solid components, it could be difficult to keep them in absolute contact with each other due to microscopic asperities on the surfaces thereof. This gives rise to a possibility that a layer of air lies between the surfaces on contact. Accordingly, in this embodiment, a material having fluidity, for example, a liquid-state material can be poured into the gap between the mounting tubular body 50 and the laser element 20 to form a connection layer 56. This helps prevent the formation of an air layer between the mounting tubular body 50 and the laser element 20. The connection layer 56 shown in the relevant figure is in a state with its thickness omitted.

In this case, as the liquid-state material to be injected, for example, resin and grease can be used. These materials usable as the liquid-state material are known as highly thermally conductive materials that have a thermal conductivity of 2 W/m·K or above. In light of the fact that the thermal conductivity of air is approximately 0.025 W/m·K, the use of the liquid-state material makes it possible to attain a higher thermal conductivity. Moreover, in the construction in which the liquid-state material is injected between the mounting tubular body 50 and the laser element 20, it is desirable to create an inlet port 55 at least at one spot of the mounting tubular body 50. The inlet port 55 merges with the gap between the mounting tubular body 50 and the laser element 20 and is made larger in dimension than the gap. This leads to an enhancement in workability. Further, the connection layer 56 may be made of any given material so long as it exhibits flowability at the time of being poured between the mounting tubular body 50 and the laser element 20, and it is thus possible to use either of such a material as may retain flowability or such a material as may solidify following the completion of the injection.

The heat-dissipating component 22 is disposed, with its mounting tubular body 50 interposed between the inner peripheral surface of the hole 46 of the housing 45 and the laser element 20. The heat-dissipating component main body 49 of the heat-dissipating component 22 is, as shown in FIG. 1, disposed so as to cover a laser driving IC 61 from the side of the optical disk 13. The laser driving IC 61 is a circuit (IC) for exercising driving control over the laser element 20. This laser driving IC 61 is also a heat-producing component whose temperature could be raised to, for example, 100° C. during its operation in the presence of heat. Moreover, the heat-dissipating plates 25 are each so arranged as to extend circumferentially about the axis of rotation L0 of the optical disk 13, with the normal extending in a direction intersected by the recording surface 38 of the optical disk 13. Each of the heat-dissipating plates 25 extends circumferentially of the optical disk 13 and is disposed inclined radially and inwardly by degrees with increasing proximity to the optical disk 13.

Moreover, it is preferable that the heat-dissipating component 22 is thermally connected to the housing 45 of the optical pickup apparatus 11 so as to release heat to the housing 45. For example, as shown in FIG. 3, the outer peripheral surface portion of the mounting tubular body 50 is connected to the inner peripheral surface portion of the hole 46 of the housing 45. In this way, the heat transferred from the semiconductor laser chip 40 to the stem 41 and the cap 42 is allowed to travel to the heat-dissipating component 22 and travel further to the housing 45. In the case of establishing connection between the heat-dissipating component 22 and the housing 45, just as in the case of forming the connection layer 56 between the mounting tubular body 50 and the laser element 20, it is desirable to form a connection layer 59 by pouring a similar fluid material into the area between the mounting tubular body 50 and the housing 45. The connection layer 59 is formed in the present embodiment. This helps facilitate the transfer of heat from the heat-dissipating component 22 to the housing 45. In addition, in this case, just as in the case of forming the connection layer 56, by creating a similar inlet port in, for example, the housing 45, it is possible to achieve an enhancement in workability.

According to the present embodiment, the heat generated in the laser element 20 which is a heat-producing component is allowed to travel to the heat-dissipating component 22 and eventually escape from the heat-dissipating component 22. Being provided with a plurality of the heat-dissipating plates 25, the heat-dissipating component 22 is large in surface area and is thus capable of offering a high heat dissipation effect. As another advantage, since the heat-dissipating portion 24 in which are provided the heat-dissipating plates 25 is disposed in the region including the side opposite from the heat-receiving portion 23 which receives heat from the laser element 20, it follows that the heat can be released at a location as far away from the laser element 20 as possible. Thus, it is possible to implement a heat dissipative structure which offers a high heat dissipation effect with a simple construction. Thereby, the laser element 20 can be cooled down effectively.

Moreover, each of the heat-dissipating plates 25 is made from a planar-shaped platy member and is thus implemented with a simple configuration. Further, the heat-dissipating portion 24 is made larger in surface area than the heat-receiving portion 23. This makes it possible to facilitate the release of the heat received by the heat-receiving portion 23 from the heat-dissipating portion 24, and thereby prevent the heat-dissipating component 22 itself from acquiring a high temperature that will eventually impair the heat dissipation effect. Accordingly, since the high heat dissipation effect can be maintained for a longer period of time, even if a reproduction operation or a recording operation is carried out for a long time, the laser element 20 can be kept in a low-temperature state.

Moreover, the heat-dissipating plates 25 are each formed as a planar-shaped plate extending circumferentially about the axis of rotation L0 of the optical disk 13. In this construction, an air current generated in accompaniment with the rotation of the optical disk 13 flows along each of the heat-dissipating plates 25. This helps facilitate heat exchange between each of the heat-dissipating plates 25 and the air current, wherefore the heat can readily be released from each of the heat-dissipating plates 25. Accordingly, a high heat dissipation effect can be attained. Further, the heat-dissipating plates 25 are each disposed inclined so as for the normal to its planar-shaped portion to extend in a direction intersected by the recording surface 38 of the optical disk 13. This makes it possible to increase the surface area of the heat-dissipating plate 25 while minimizing the dimension of the heat-dissipating plate 25 in a direction substantially parallel to the axis of rotation L0 of the optical disk 13. In this way, a construction which is made compact and nevertheless offers a high heat dissipation effect can be realized.

Moreover, the heat-dissipating component main body 49 is shaped like a drainboard so as to provide air permeability in the thicknesswise direction. Therefore, an air current generated in accompaniment with the rotation of the optical disk 13 can be guided by each of the heat-dissipating plates 25 so as to pass through the region around the laser element 20 and the laser driving IC 61. In this way, it is possible to realize an air-cooling effect for allowing direct heat exchange between air and the laser element 20 as well as the laser driving IC 61. In particular, like the present embodiment, in the construction in which the heat-dissipating plates 25 are each disposed inclined, an air current is guided by the heat-dissipating plates 25 to pass through the heat-dissipating component main body 49 easily in the thicknesswise direction. This helps enhance the aforementioned air-cooling effect. Thus, in the heat dissipative structure 10, not only the laser element 20 to which is connected the heat-dissipating component 22, but also the laser driving IC 61 which is another heat-producing component, can forcibly be air-cooled.

Moreover, the optical pickup apparatus 11 is, following the completion of recording with respect to the optical disk 13 (DVD-R, for example) in the direction from the inner radius to the outer radius of the disk, moved to an RMA area located at the innermost radius of the disk. At this time, the optical pickup apparatus 11 is brought close to a motor for rotating the optical disk 13 in a heat-liberating state, in consequence whereof the laser element 20 and the laser driving IC 61 are each prone to rise in temperature. In the present embodiment, as has already been described, each of the heat-dissipating plates 25 extends circumferentially of the optical disk 13 and is inclined radially and inwardly by degrees with increasing proximity to the optical disk 13. In this construction, at the time when the optical pickup apparatus 11 is moved from the outer radius to the inner radius of the optical disk 13, the laser element 20 and the laser driving IC 61 can forcibly be air-cooled. Accordingly, even in a state where the optical pickup apparatus 11 is located near the motor, occurrence of a malfunction can be prevented.

Moreover, in the heat-dissipating component 22, at least part of the heat-dissipating portion 24, for example, the heat-dissipating portion 24 in its entirety, may be applied with a surface treatment to obtain a higher thermal emissivity. In this case, by means of plating or oxidative surface treatment, for example, black-color alumite treatment, or by means of application of a matte black coating, an enhancement in thermal emissivity can be achieved. Alternatively, in addition to the black-color alumite treatment, black-color chromium plating may also be adopted. Such surface treatment contributes to an enhancement in emissivity [ε]. For example, in a case where a material having a relatively low emissivity e.g. an emissivity of approximately 0.4, such as aluminum and zinc, is applied with the aforementioned surface treatment, the emissivity can be increased to approximately 0.9. In this way, the thermal emissivity of the heat-dissipating component 22 can be increased thereby to enhance the heat dissipation effect. Further, at least part of the heat-dissipating portion 24, for example, the heat-dissipating portion 24 in its entirety, may be given a rough face by means of graining treatment or otherwise. In this case, it is possible to increase the surface area of the heat-dissipating component 22 without the necessity of increasing the outer dimension of the heat-dissipating component 22, and thereby enhance the heat dissipation effect.

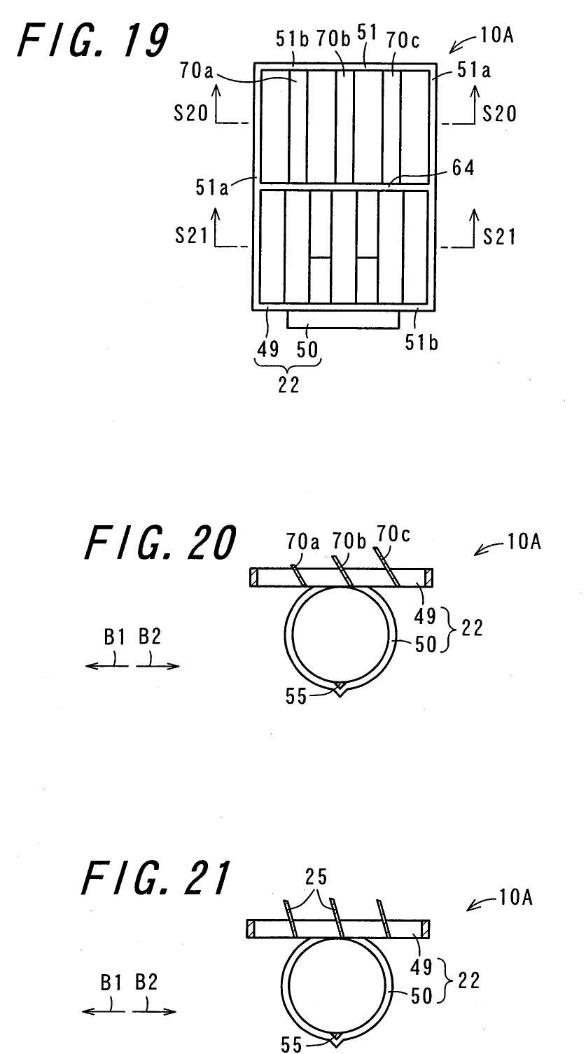

FIG. 19 is a front view showing a heat dissipative structure 10A in accordance with another embodiment of the invention. FIG. 20 is a sectional view of the heat dissipative structure 10A taken along the section line S20-S20 of FIG. 19. FIG. 21 is a sectional view of the heat dissipative structure 10A taken along the section line S21-S21 of FIG. 19. The heat dissipative structure 10A of this embodiment is analogous to the heat dissipative structure 10 of the preceding embodiment shown in FIGS. 1 through 18. Therefore, the components that play the same or corresponding roles as in the heat dissipative structure 10 will be identified with the same reference symbols, and only the points of difference in the construction will be explained hereinbelow and the description of similar configurations will be omitted. The heat dissipative structure 10A of this embodiment differs from the heat dissipative structure 10 shown in FIGS. 1 through 18 only in the configuration of the heat-dissipating component main body 49 of the heat-dissipating component 22. Otherwise, the heat dissipative structure 10A has the same construction as that of the heat dissipative structure 10.

In the heat-dissipating component main body 49 of the present embodiment, the framework 51 is provided with a cross member 64 which provides connection between the midportions of one and the other of one pair of edge portions 51a. In this way, the part inside the framework 51 is divided into two regions by the cross member 64. One of the two regions, which is coupled to the mounting tubular body 50 (hereinafter referred to as “one region”), includes heat-dissipating plates 25 similar to those shown in FIGS. 1 through 18. The heat-dissipating plates 25 are each so disposed as to extend between the cross member 64 and, out of the other pair of edge portions 51b of the framework 51, the one located closer to the mounting tubular body 50. The other of the two regions opposite to the region which is coupled to the mounting tubular body 50 (hereinafter referred to as “the other region”) includes a plurality of, for example, three pieces of heat-dissipating plates 70a through 70c that are different from the above-described heat-dissipating plates 25 in width dimension.

Each of the heat-dissipating plates 70a through 70c of the other region is, like the heat-dissipating plate 25 of one region, formed as a strip-like rectangular plate which extends in the same direction as that in which the heat-dissipating plate 25 of one region extends and is disposed inclined in a similar manner. Each of the heat-dissipating plates 70a through 70c of the other region is so disposed as to extend between the cross member 64 and, out of the other pair of edge portions 51b of the framework 51, the one located away from the mounting tubular body 50. While the heat-dissipating plates 70a through 70c of the other region may be made to have the same width dimension, in this embodiment, they differ from one another in width dimension. For example, the heat-dissipating plates 70a through 70c are arranged in order of increasing width dimension with approach towards the radially outer side of the optical disk 13. The term “width dimension” refers to the dimension of each of the heat-dissipating plates 70a through 70c as observed in a direction which extends along the planar-shaped portion thereof and is intersected by the axis L50 of the mounting tubular body 50. Being made differently from one another in terms of width dimension in that way, the heat-dissipating plates 70a through 70 differ from one another also in the degree of extension from the other thicknesswise side of the framework 51.

By designing the heat-dissipating plates 70a through 70 in such a manner that they differ from one another in one of width dimension and shape, it is possible for all of the heat-dissipating plates 70a through 70 to make contact with an air current with ease. This helps enhance the heat dissipation effect. Accordingly, at the time when the optical pickup apparatus 11 is moved from the outer radius to the inner radius of the optical disk 13, a current of air can be received effectively. In the present embodiment, the heat-dissipating plates 70a through 70 are made to have different width dimensions. By virtue of the construction in which the part inside the framework 51 is divided into a plurality of regions and the heat-dissipating plates 25 and 70a through 70 to be disposed therein are made to have different configurations, how an air current is to be taken in can be varied from region to region.

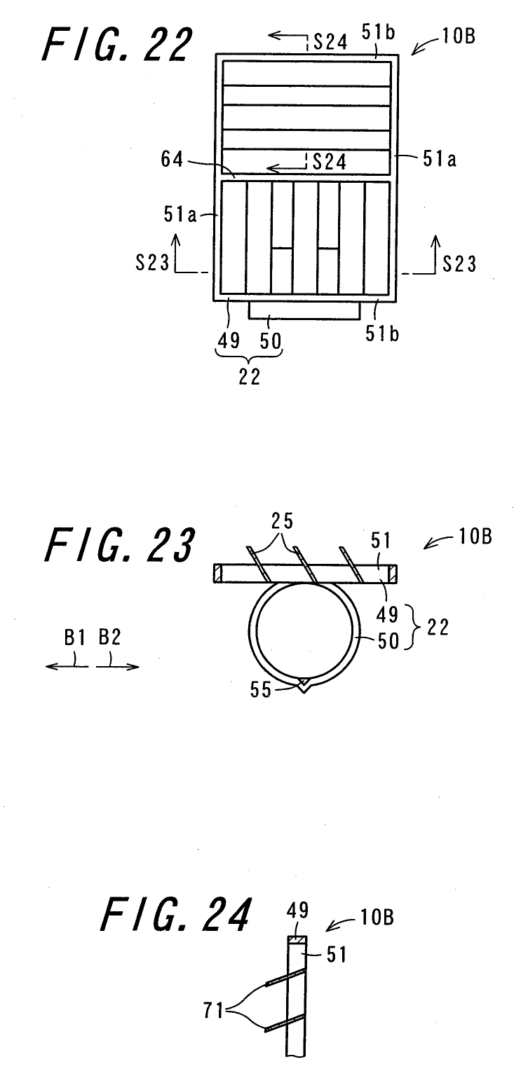

FIG. 22 is a front view showing a heat dissipative structure 10B in accordance with still another embodiment of the invention. FIG. 23 is a sectional view of the heat dissipative structure 10B taken along the section line S23-S23 of FIG. 22. FIG. 24 is a sectional view of the heat dissipative structure 10B taken along the section line S24-S24 of FIG. 22. The heat dissipative structure 10B of this embodiment is analogous to the heat dissipative structure 10A of the preceding embodiment shown in FIGS. 19 through 21. Therefore, the components that play the same or corresponding roles as in the heat dissipative structure 10A will be identified with the same reference symbols, and only the points of difference in the construction will be explained hereinbelow and the description of similar configurations will be omitted. The heat dissipative structure 10B of this embodiment differs from the heat dissipative structure 10A shown in FIGS. 19 through 21 only in the configuration of the heat-dissipating component main body 49 of the heat-dissipating component 22. Otherwise, the heat dissipative structure 10B has the same construction as that of the heat dissipative structure 10A.

In this embodiment, like the heat dissipative structure 10A shown in FIGS. 19 through 21, the framework 51 is provided with a cross member 64 so that the part inside the framework 51 can be divided into two regions. One of the two regions, namely one region, as is the case with the heat dissipative structure 10A shown in FIGS. 19 through 21, includes the heat-dissipating plates 25. The other of the two regions, namely the other region includes a plurality of, for example, two pieces of heat-dissipating plates 71 that extend in a direction perpendicular to the direction in which the heat-dissipating plates 25 of one region extend. The heat-dissipating plates 71 of the other region are similarly configured and are each, like the heat-dissipating plate 25 of one region, formed as a strip-like rectangular plate. The heat-dissipating plates 71 of the other region are each so disposed as to extend between one pair of edge portions 51a of the framework 51. Each of the heat-dissipating plates 71 of the other region is so disposed that the normal to its planar-shaped portion extends in a direction intersected by the recording surface 38 of the optical disk 13. The heat-dissipating plates 71 of the other region are each formed as a planar-shaped plate extending substantially in the direction of the radius of the optical disk 13, and are each inclined gradually toward the upstream side in a disk rotational direction A with increasing proximity to the optical disk 13.

In this construction, in each of the heat-dissipating plates 25 of one region, at the time when the optical pickup apparatus 11 is moved from the outer radius to the inner radius of the optical disk 13, a current of air can be received effectively, thereby allowing the laser element 20 and the laser driving IC 61 to be exposed readily to the air current. On the other hand, in each of the heat-dissipating plates 71 of the other region, an air current generated in accompaniment with the rotation of the optical disk 13 can be received effectively, thereby allowing the laser element 20 and the laser driving IC 61 to be exposed readily to the air current. By virtue of such a combination of the heat-dissipating plates 25 and the heat-dissipating plates 71, the laser element 20 and the laser driving IC 61 can forcibly be air-cooled in an effective manner.

As has heretofore been described, according to the heat dissipative structures 10, 10A, and 10B embodying the invention, not only it is possible for the heat liberated from the laser element 20, or equivalently, a heat-producing component which is not thermally connected, to be radiated into the air successfully, but it is also possible for the laser driving IC 61, or equivalently, a heat-producing component which is not thermally connected, to be forcibly air-cooled. Thereby, a significant decrease in temperature can be achieved in the heat-producing component. As another advantage, the heat received from the laser element 20 can be transmitted to the housing 45, wherefore the heat dissipation effect can be enhanced.

With the provision of the heat dissipative structures 10, 10A, and 10B thus constructed, the following effects (1) through (4) can be accomplished:

(1) there is no deterioration of signal detection capability resulting from heat generation occurring in a light-emitting element such as the laser element 20 as well as in an integrated electronic component such as the laser driving IC 61;

(2) it is possible to suppress the shortening of the service life of the laser element 20 as well as the laser driving IC 61 resulting from heat generation occurring in itself;

(3) a reduction in operating current is achieved by lessening self-induced heat in the laser element 20 and the laser driving IC 61 under operating conditions and in particular by suppressing its own temperature rise under high temperature conditions, whereby the shortening of the service life of the element during operation under high temperature conditions can be suppressed, and also, by virtue of the reduction of the operating current, energy conservation can be accomplished; and

(4) even if the adhesive used to secure the laser element 20 to the housing 45 is softened by heat in the course of production and consequently the laser element 20 undergoes a change in fixed position, the heat dissipation effect will not be adversely affected, wherefore performance degradation in the optical pickup apparatus 11 can be prevented.

Note that the embodiments thus far described are considered as illustrative only of the invention, and therefore modifications or changes may be made in the constructions of the embodiments within the scope of the invention. For example, in the above-described embodiments, the heat-dissipating component 22 is thermally connected to the laser element 20 and the laser driving IC 61 is forcibly air-cooled, for example, the laser driving IC 61 is subjected to air-cooling at the time when the optical pickup apparatus 11 is slidingly moved from the outer radius side to the inner radius side. In contrast to this, alternatively, the heat-dissipating component 22 may be thermally connected to the laser driving IC 61 and the laser element 20 may be forcibly air-cooled, for example, the laser element 20 may be subjected to air-cooling at the time when the optical pickup apparatus 11 is slidingly moved from the outer radius side to the inner radius side. The heat-producing component may also be a component other than the laser element 20 and the laser driving IC 61. Moreover, the configuration of the heat-dissipating component 22 may be altered. The materials, dimensions, and so forth to be adopted are not limited to those as suggested in the above description, but may be changed in an appropriate manner.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A heat dissipative structure that is to be provided in an optical pickup apparatus in which a heat-producing component is mounted, comprising:
a heat-dissipating component to be thermally connected to the heat-producing component, the heat dissipating component having a heat-receiving portion which receives heat from the heat-producing component, and a heat-dissipating portion disposed in a region including a side opposite from the heat-receiving portion,
wherein the heat-dissipating portion includes a heat-dissipating plate for releasing heat.

2. The heat dissipative structure of claim 1, wherein the heat-producing component is a semiconductor laser element or a laser driving IC.

3. The heat dissipative structure of claim 1, wherein the heat-dissipating plate is formed of a planar-shaped platy member.

4. The heat dissipative structure of claim 1, wherein, in the heat-dissipating component, at least part of the heat-dissipating portion is applied with a surface treatment to obtain higher thermal emissivity.

5. The heat dissipative structure of claim 1, wherein, in the heat-dissipating component, at least part of the heat-dissipating portion is applied with a matte black coating to obtain higher thermal emissivity.

6. The heat dissipative structure of claim 1, wherein, in the heat-dissipating component, at least part of the heat-dissipating portion is made to have a rough face.

7. The heat dissipative structure of claim 1, wherein the heat-dissipating portion is made larger in surface area than the heat-receiving portion.

8. The heat dissipative structure of claim 1, wherein the heat-dissipating component and the heat-producing component are indirectly connected to each other via a connection layer having thermal conductivity.

9. The heat dissipative structure of claim 8, wherein the connection layer is formed by injection of a material having fluidity.

10. The heat dissipative structure of claim 9, wherein in the heat-dissipating component is formed at least one opening for injecting the material having fluidity in between the heat-dissipating component and the heat-producing component.

11. The heat dissipative structure of claim 1, wherein the heat-dissipating component has a plurality of heat-dissipating plates that are spacedly arranged side by side.

12. The heat dissipative structure of claim 11, wherein the heat-dissipating plates have different dimensions.

13. The heat dissipative structure of claim 12, wherein the heat-dissipating component is thermally connected to a housing of the optical pickup apparatus.

14. An optical pickup apparatus comprising:
a heat-producing component; and
the heat dissipative structure of claim 1.

15. The optical pickup apparatus of claim 14, wherein the optical pickup apparatus is slidably disposed on a plurality of shafts arranged substantially in parallel with each other and is thus movable reciprocally along each of the shafts, and the optical pickup apparatus is designed to perform at least one of information reproduction and information recording with respect to an optical disk which is arranged substantially in parallel with the axis of each of the shafts, and
the heat-dissipating plate is formed as a planar-shaped plate extending circumferentially about the axis of rotation of the optical disk, with a normal to its planar-shaped portion extending in a direction intersected by a recording surface of the optical disk.

16. The optical pickup apparatus of claim 14, wherein the optical pickup apparatus is slidably disposed on a plurality of shafts arranged substantially in parallel with each other and is thus movable reciprocally along each of the shafts, and the optical pickup apparatus is designed to perform at least one of information reproduction and information recording with respect to an optical disk which is arranged substantially in parallel with the axis of each of the shafts, and
the heat-dissipating plate is formed as a planar-shaped plate extending in a direction substantially radial to the optical disk, with a normal to its planar-shaped portion extending in a direction intersected by the recording surface of the optical disk.

17. An optical recording/reproducing apparatus in which is mounted the optical pickup apparatus of claim 14.
